(19) United States
(12) Patent Application Publication
(10) Pub. No.: US 2026/0255551 A1
(43) Pub. Date: Aug. 27, 2026

(54) HEAT DISSIPATION PLATE, HEAT DISSIPATION DEVICE, AND COMPUTING DEVICE

(71) Applicants: Inventec (Pudong) Technology Corporation, Shanghai (CN); INVENTEC CORPORATION, Taipei (TW)

(72) Inventor: Biao Li, Shanghai (CN)

(21) Appl. No.: 19/207,353

(22) Filed: May 14, 2025

(30) Foreign Application Priority Data
Feb. 25, 2025 (CN) 202510213655.5

(51) Int. Cl. H05K 7/20; G06F 1/20

(52) U.S. Cl. CPC H05K 7/20809; G06F 1/20; H05K 7/20309; H05K 7/20318; H05K 7/20336

(57) ABSTRACT

A heat dissipation plate, a heat dissipation device, and a computing device are provided. The heat dissipation plate includes a frame provided with a first accommodating cavity, a second accommodating cavity, and a first opening; a cooling plate mounted in the first accommodating cavity, the cooling plate being provided with a liquid cooling cavity configured to receive a liquid cooling medium, the cooling plate being provided with a liquid inlet and a liquid outlet; and a heat spreading plate including a plurality of protrusions, the plurality of protrusions being spaced apart along a first direction of the heat dissipation plate, an end of the cooling plate connected to the heat spreading plate being provided with a plurality of grooves, the plurality of protrusions being provided in the plurality of grooves in a one-to-one correspondence, and a phase change medium being provided inside the heat spreading plate.

### CROSS-REFERENCE TO RELATED APPLICATIONS

This application claims priority of Chinese Patent Application No. 202510213655.5, filed on Feb. 25, 2025, entitled “HEAT DISSIPATION PLATE, HEAT DISSIPATION DEVICE, AND COMPUTING DEVICE”, the entire content of which is incorporated herein by reference in its entirety.

### TECHNICAL FIELD

The present disclosure relates to the technical field of computer accessories, and in particular to a heat dissipation plate, a heat dissipation device, and a computing device.

### BACKGROUND

With the acceleration of the global digitization process and the explosive growth of computing power demand, the power of server chips is increasing in the process of iterative upgrading, and the requirements for heat dissipation are also increasing.

In order to meet the increasing heat dissipation requirements of server chips, the heat dissipation capacity of heat dissipation devices needs to be continuously improved. The current heat dissipation device is a cooling plate radiator, which takes away heat on surfaces of the server chip by a liquid cooling medium flowing inside a cooling plate of the cooling plate radiator, but the liquid cooling medium, as a single-phase liquid, has limited convection heat exchange capacity and is difficult to meet the heat dissipation requirements of high-power chips. Therefore, the current heat dissipation device has the defects of low heat exchange efficiency and poor heat dissipation capacity.

### SUMMARY

Accordingly, it is necessary to provide a heat dissipation plate, a heat dissipation device, and a computing device to address the problems of low heat exchange efficiency and poor heat dissipation capacity of the heat dissipation device.

The present disclosure provides a heat dissipation plate, which includes:
a frame provided with a first accommodating cavity, a second accommodating cavity, and a first opening, the first accommodating cavity being in communication with the second accommodating cavity, and the first opening being in communication with the second accommodating cavity;
a cooling plate mounted in the first accommodating cavity, the cooling plate being provided with a liquid cooling cavity configured to receive a liquid cooling medium, the cooling plate being provided with a liquid inlet and a liquid outlet, and the liquid inlet and the liquid outlet being both in communication with the liquid cooling cavity; and
a heat spreading plate mounted in the second accommodating cavity, the heat spreading plate including an evaporation end surface and a condensation end surface, the evaporation end surface being facing the first opening, the condensation end surface being connected to the cooling plate, the heat spreading plate including a plurality of protrusions provided on the condensation end surface, the plurality of protrusions being spaced apart along a first direction of the heat dissipation plate, an end of the cooling plate connected to the heat spreading plate being provided with a plurality of grooves, the plurality of protrusions being provided in the plurality of grooves in a one-to-one correspondence, and a phase change medium being provided inside the heat spreading plate.

The present disclosure further provides a heat dissipation device, which includes a water pump, a first pipeline, a second pipeline, a water tank, and the heat dissipation plate in any one of the above embodiments. An output end of the water tank and the liquid inlet of the heat dissipation plate are connected through the first pipeline, the liquid outlet of the heat dissipation plate and an input end of the water tank are connected through the second pipeline, the water tank, the heat dissipation plate, the first pipeline and the second pipeline are sequentially connected to form a circulation system, and the water pump is provided in the circulation system.

The present disclosure further provides a computing device, which includes a computing element and the heat dissipation device described of the above embodiment. The heat dissipation device is mounted on the computing element.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is a schematic view of a heat dissipation plate according to an embodiment of the present disclosure.

FIG. 2 is a schematic view of a heat dissipation plate according to another embodiment of the present disclosure.

### DESCRIPTION OF REFERENCE NUMERALS

100, frame; 100A, first accommodating cavity; 100B, second accommodating cavity; 100C, first opening; 100D, second opening; 110, fastener; 120, limiting portion;
200, cooling plate; 210A, liquid cooling cavity; 210B, liquid inlet; 210C, liquid outlet; 210D, groove;
300, heat spreading plate; 301, protrusion; 301A, second vacuum cavity; 311, evaporation end surface; 312, condensation end surface; 310A, first vacuum cavity; 320, capillary wick; 330, supporting member.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

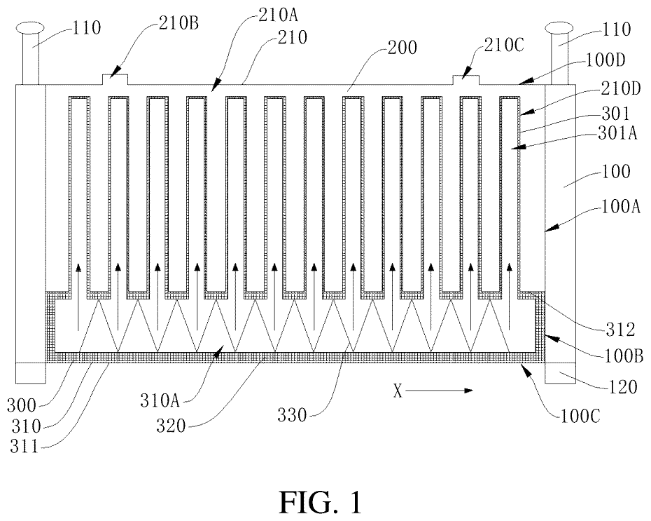

Referring to FIG. 1, a heat dissipation plate according to an embodiment of the present disclosure is shown. The heat dissipation plate includes a frame 100, a cooling plate 200, and a heat spreading plate 300. The frame 100 is provided with a first accommodating cavity 100A, a second accommodating cavity 100B, and a first opening 100C. The first accommodating cavity 100A is in communication with the second accommodating cavity 100B, and the first opening 100C is in communication with the second accommodating cavity 100B. The cooling plate 200 is mounted in the first accommodating cavity 100A. The cooling plate 200 is provided with a liquid cooling cavity 210A configured to a liquid cooling medium. The cooling plate 200 is provided with a liquid inlet 210B and a liquid outlet 210C. The liquid inlet 210B and the liquid outlet 210C are both in communication with the liquid cooling cavity 210A. The heat spreading plate 300 is mounted in the second accommodating cavity 100A. The heat spreading plate 300 includes an evaporation end surface 311 and a condensation end surface 312. The evaporation end surface 311 faces the first opening 100C, and the condensation end surface 312 is connected to the cooling plate 200. The heat spreading plate 300 includes a plurality of protrusions 301 provided on the condensation end surface 312. The plurality of protrusions 301 are spaced apart along a first direction of the heat dissipation plate. An end of the cooling plate 200 connected to the heat spreading plate 300 is provided with a plurality of grooves 210D. The plurality of protrusions 301 are provided in the plurality of grooves 210D in a one-to-one correspondence. A phase change medium is provided inside the heat spreading plate 300. The first direction of the heat dissipation plate is a length direction of the heat dissipation plate, as shown in an X-axis direction of FIG. 1.

In an optional embodiment, the frame 100 is of a cubic structure, and the cooling plate 200 and the heat spreading plate 300 are arranged in the frame 100 in a stacked manner.

In an optional embodiment, as shown in FIG. 1, the first accommodating cavity 100A is located above the second accommodating cavity 100B, and an element to be cooled (such as a computing element) is located below the second accommodating cavity 100B. Specifically, the first accommodating cavity 100A is provided at an end of the second accommodating cavity 100B away from the element to be cooled, and the cooling plate 200 is connected to an end of the heat spreading plate 300 away from the element to be cooled.

According to the heat dissipation plate in the embodiment of the present disclosure the cooling plate 200 is mounted in the first accommodating cavity 100A of the frame 100, and the heat spreading plate 300 is mounted in the second accommodating cavity 100B of the frame 100. The cooling plate 200 is connected to the condensation end surface 312 of the heat spreading plate 300. The condensation end surface 312 of the heat spreading plate 300 is provided with the plurality of protrusions 301, and the cooling plate 200 is provided with a plurality of grooves 210D, so that the protrusions 301 are fitted into the grooves 210D. The evaporation end surface 311 of the heat spreading plate 300 is configured to be mounted on the element to be cooled. The heat generated by the element to be cooled is transferred to the heat spreading plate 300, so that the phase change medium absorbs the heat and is evaporated into gas from liquid. As shown by arrow directions in the heat spreading plate 300 in FIG. 1, and the phase change medium rises into the protrusion 301 after being changed into gas. Since the liquid cooling medium is input into the liquid cooling cavity 210A of cooling plate 200 through the liquid inlet 210B, the groove 210D of the cooling plate 200 wraps the protrusion 301 of the heat spreading plate 300, that is, the protrusion 301 serves as a heat dissipation fin of the heat spreading plate 300, thereby increasing a contact area between the cooling plate 200 and the heat spreading plate 300, so that the heat of the heat spreading plate 300 is transferred to the cooling plate 200 more quickly, and an evaporated gaseous phase change medium is condensed into a liquid phase change medium. The alternating process of evaporation and condensation inside the heat spreading plate 300 will take away a large amount of heat.

According to the heat dissipation plate in the embodiment of the present disclosure the phase change medium is provided in the heat spreading plate 300. Through the phase change heat transferring of liquid evaporation and gas condensation of the phase change medium, the heat generated by the element to be cooled is transferred to the cooling plate 200 and taken away by the liquid cooling medium. Compared with the convection heat transfer of the conventional cooling plate, more heat can be transferred in a short time, which can significantly enhance the heat dissipation capacity of the heat dissipation plate, thereby reducing the temperature of the element to be cooled, and the heat dissipation plate has the advantages of high heat exchange efficiency and good heat dissipation capacity.

In an exemplary embodiment, the heat dissipation plate works in such a way that the evaporation end surface 311 of the heat dissipation plate is in contact with a packaging surface of the element to be cooled through a thermally conductive contact material. The thermally conductive contact material may be a thermally conductive paste, a thermally conductive gasket, a thermally conductive filler, etc.

In some embodiments, as shown in FIG. 1, the heat spreading plate 300 includes a capillary wick 320 and is provided with a first vacuum cavity 310A. The phase change medium is provided in the first vacuum cavity 310A. The protrusion 301 is provided with a second vacuum cavity 301A in communication with the first vacuum cavity 310A. The capillary wick 320 covers an inner wall of the first vacuum cavity 310A and/or an inner wall of the second vacuum cavity 301A. By providing the sealed first vacuum cavity 310a inside the heat spreading plate 300 and providing the second vacuum cavity 310A in communication with the first vacuum cavity 310A on the protrusion 301, the sealed first vacuum cavity 310A and the second vacuum cavity 301A can ensure that the phase change medium can efficiently circulate in the heat spreading plate 300. The phase change medium is provided in the first vacuum cavity 310A. When the phase change medium is heated to become a gaseous state and rises to the second vacuum cavity 301A, the protrusion 301, as the heat dissipation part of the heat spreading plate 300, accelerates the heat transfer to the cooling plate 200, so that the gaseous phase change medium is changed back to the liquid phase change medium. The capillary wick 320 covers the inner wall of the first vacuum cavity 310A and the inner wall of the second vacuum cavity 301A. Driven by the capillary force, the liquid phase change medium condensed in the protrusion 301 flows back to the evaporation end surface 311 to form a circulation backflow of the phase change medium.

Furthermore, the heat spreading plate 300 includes a supporting member 330. One end of the supporting member 330 is connected to the evaporation end surface 311, and the other end of the supporting member 330 is connected to the condensation end surface 312. The supporting member 330 is also provided in the first vacuum cavity 310A, and two ends of the supporting member 330 are connected to the evaporation end surface 311 and the condensation end surface 312, respectively, so as to provide a supporting force for the evaporation end surface 311 and the condensation end surface 312, prevent the heat spreading plate 300 from being deformed by pressure, and maintain the stability of the first vacuum cavity 310A.

In an exemplary embodiment, the supporting member 330 is of a cylindrical structure, and two ends of the supporting member 330 are respectively connected to the evaporation end surface 311 and the condensation end surface 312.

In an exemplary embodiment, the heat spreading plate 300 is made of a metal with high thermal conductivity, such as copper or copper-aluminum alloy, so as to improve the thermal conductivity of the heat spreading plate 300 and further improve the heat dissipation efficiency of the heat dissipation plate. In other embodiments, the heat spreading plate 300 may be made of aluminum, so as to adapt to some lightweight scenarios.

In an exemplary embodiment, the supporting member 330 is made of the same metal material as the heat spreading plate 300, so that the supporting member 330 provides a certain strength support for the heat spreading plate 300.

In an optional embodiment, the protrusion 301 and the heat spreading plate 300 are integrally formed. By configuring the protrusion 301 to be integrally connected to the heat spreading plate 300, the first vacuum cavity 310A and the second vacuum cavity 301A are configured as sealed vacuum cavities, so as to improve the sealing and stability of the first vacuum cavity 310A and the second vacuum cavity 301A, thereby improving the use stability of the heat dissipation plate.

In an optional embodiment, as shown in FIG. 1, a plurality of the supporting members 330 are provided. One end of each supporting member 330 is obliquely arranged with respect to the evaporation end surface 311, the other end of each supporting member 330 is obliquely arranged with respect to the condensation end surface 312, and the plurality of supporting members 330 are sequentially connected end to end in the first vacuum cavity 310A to form a zigzag line structure. By configuring the supporting member 330 in an inclined state with respect to the end surfaces of the heat spreading plate 300 and connecting the plurality of supporting members 330 into a zigzag line structure, the support structure of the supporting members 330 is more stable, thereby avoiding deformation of the evaporation end face 311 and the condensation end face 312 of the heat spreading plate 300, which would cause the connection between the heat spreading plate 300 and the cooling plate 200 to be not tight enough, thereby avoiding affecting the conduction of heat and improving the heat dissipation efficiency of the heat dissipation plate. Furthermore, the supporting member 330 in an inclined state can also be used to guide the phase change medium condensed into a liquid state, so that the phase change medium forms a circulation.

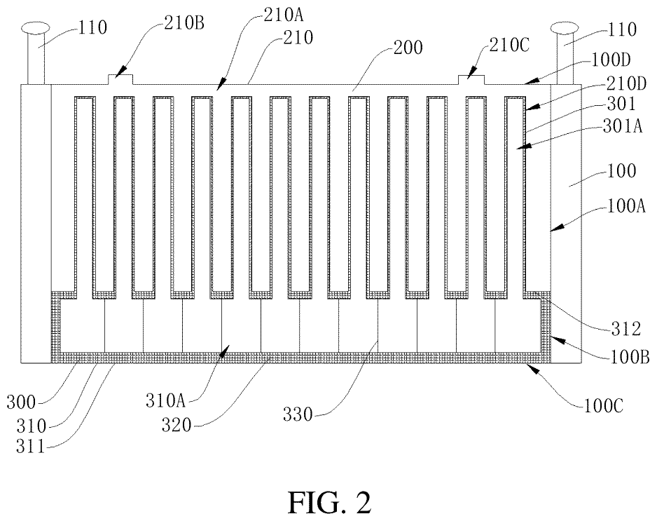

In other embodiments, as shown in FIG. 2, one end of each supporting member 330 is vertically connected to the evaporation end surface 311, and the other end of each supporting member 330 is vertically connected to the condensation end surface 312. The supporting member 330 is configured to be vertically connected to the evaporation end surface 311 and the condensation end surface 312, which can also provide a support force for the heat spreading plate 300 and prevent the heat spreading plate 300 from being deformed.

In an optional embodiment, as shown in FIG. 1, the heat dissipation plate further includes a limiting portion 120 connected to an end of the frame 100 adjacent to the first opening 100C. By arranging the limiting portion 120 at the end of the frame 100 adjacent to the first opening 100C, when the heat dissipation plate is mounted on the element to be cooled, the limiting portion 120 can be clamped on a side of the element to be cooled, so that the heat dissipation plate can be mounted more accurately, thereby ensuring that the heat spreading plate 300 of the heat dissipation plate corresponds to the position of the element to be cooled and ensuring the heat dissipation effect of the heat dissipation plate.

In an exemplary embodiment, a gap is provided between the heat spreading plate 300 and the first opening 100C, so that the frame 100 forms the limiting portion 120 protruding from the evaporation end surface 311 of the heat spreading plate 300.

In an exemplary embodiment, as shown in FIG. 2, the evaporation end surface 311 of the heat spreading plate 300 is flush with the first opening 100C. By limiting the heat spreading plate 300 inside the second accommodating cavity 100B of the frame 100, the heat spreading plate 300 is ensured to be stably mounted.

In an optional embodiment, the capillary wick 320 is a wire mesh type capillary wick, a sintered type capillary wick or a grooved type capillary wick. The wire mesh type capillary wick is formed by stacking a plurality of layers of metal wire woven meshes. The wire mesh type capillary wick has high permeability and low flow resistance to the gaseous phase change medium. The sintered type capillary wick has a porous structure formed by sintering metal powder at a high temperature, and the capillary force of the sintered type capillary wick is extremely strong, so that the phase change medium can be quickly pumped back to the evaporation end face 311. The grooved type capillary wick has fine grooves formed on an inner wall of the heat spreading plate 300 by mechanical or chemical etching, and the diffusion channel of the gaseous phase change medium is open, and the permeability is the highest. Through the differentiated design of the capillary wick 320, the heat dissipation plate can accurately match the thermal management requirements of different scenarios and achieve the optimal balance of efficiency, cost and reliability.

In an optional embodiment, the phase change medium is high-purity water or ethanol. The latent heat of evaporation of high-purity water is 2260 kJ/kg. The unit mass of medium can absorb more heat, which is suitable for high-power heat dissipation scenarios. The freezing point of ethanol is as low as −114° C., which is suitable for extremely low temperature environments and can prevent the phase change medium from freezing and failing. By rationally selecting the phase change medium, the heat dissipation plate can accurately match the heat source characteristics and environmental conditions to maximize the heat dissipation efficiency and reliability.

In an optional embodiment, as shown in FIG. 1, a side of the frame 100 opposite to the first opening 100C is provided with a second opening 100D. An end surface of the cooling plate 200 away from the heat spreading plate 300 faces the second opening 100D. The liquid inlet 210B and the liquid outlet 210C are both provided on an end surface of the cooling plate 200 away from the heat spreading plate 300. By arranging the second opening 100D on the side of the frame 100 opposite to the first opening 100C, the liquid inlet 210B and the liquid outlet 210C on the cooling plate 200 are arranged at the second opening 100D, which facilitates the connection of the liquid inlet 210B and the liquid outlet 210C to the pipeline, and has the advantage of convenient operation.

In an alternative embodiment, as shown in FIG. 1, the heat dissipation plate further includes a fastener 110 provided on the frame 100. The fastener 110 is configured to connect the frame 100 to the element to be cooled. The heat dissipation plate can be mounted on the element to be cooled through the fastener 110, so that the heat dissipation plate and the element are tightly connected, thereby transferring the heat from the element to the heat dissipation plate.

In an exemplary embodiment, the fastener 110 includes two bolts provided on two sides of the frame 100, respectively. The frame 100 is provided with two connection holes, and the two bolts are connected to the element to be cooled through the two connection holes. The heat dissipation plate is fixed on the element to be cooled by bolts, so that the heat dissipation plate and the element are tightly connected to ensure the heat dissipation effect of the heat dissipation plate.

In another exemplary embodiment, the fastener 110 is a buckle, the element to be cooled is provided with a claw that cooperates with the buckle. The buckle is configured to be detachably connected to the claw of the element to be cooled, so that the heat dissipation plate is fixedly connected to the element to be cooled, and has the advantage of convenient disassembly.

On the other hand, an embodiment of the present disclosure further provides a heat dissipation device, which includes a water pump, a first pipeline, a second pipeline, a water tank, and the heat dissipation plate described in any one of the above embodiments. An output end of the water tank and the liquid inlet 210B of the heat dissipation plate are connected through the first pipeline. The liquid outlet 210C of the heat dissipation plate and an input end of the water tank are connected through the second pipeline. The water tank, the heat dissipation plate, the first pipeline and the second pipeline are sequentially connected to form a circulation system, and the water pump is provided in the circulation system.

According to the heat dissipation device of the present embodiment, the liquid cooling medium in the water tank is input into the heat dissipation plate through the water pump, so that the heat in the heat dissipation plate is taken away, and the purpose of cooling is achieved. The heat dissipation plate is provided with the phase change medium in the heat spreading plate 300, through the phase change heat transfer of liquid evaporation and gas condensation of the phase change medium, the heat on the element to be cooled is transferred to the cooling plate 200 and taken away by the liquid cooling medium. Compared with the convection heat transfer of the cooling plate 200, more heat can be transferred in a short time, which can significantly enhance the heat dissipation capacity of the heat dissipation plate, thereby reducing the temperature of the element, and the heat dissipation plate has the advantages of high heat exchange efficiency and good heat dissipation capacity.

On the other hand, an embodiment of the present disclosure further provides a computing device, which includes a computing element and the heat dissipation device described in any one of the above embodiments. The heat dissipation device is mounted on the computing element.

According to the computing device of the present embodiment, the heat dissipation device is mounted on the computing element to dissipate heat from the computing element, thereby ensuring stable operation of the computing element. The heat dissipation device is provided with the heat dissipation plate connected to the computing element. The heat dissipation plate is provided with the phase change medium in the heat spreading plate 300, through the phase change heat transfer of liquid evaporation and gas condensation of the phase change medium, the heat on the element to be cooled is transferred to the cooling plate 200 and taken away by the liquid cooling medium. Compared with the convection heat transfer of the cooling plate 200, more heat can be transferred in a short time, which can significantly enhance the heat dissipation capacity of the heat dissipation plate, thereby reducing the temperature of the element. Under the condition of computing elements with the same power consumption, the heat dissipation plate of the present embodiment can allow a higher water inlet temperature, which can reduce the power of the heat dissipation plate, save the operating cost of the heat dissipation plate, and has the advantages of high heat exchange efficiency and good heat dissipation capacity.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A heat dissipation plate, comprising:
a frame provided with a first accommodating cavity, a second accommodating cavity, and a first opening, the first accommodating cavity being in communication with the second accommodating cavity, and the first opening being in communication with the second accommodating cavity;
a cooling plate mounted in the first accommodating cavity, the cooling plate being provided with a liquid cooling cavity configured to receive a liquid cooling medium, the cooling plate being provided with a liquid inlet and a liquid outlet, and the liquid inlet and the liquid outlet being both in communication with the liquid cooling cavity; and
a heat spreading plate mounted in the second accommodating cavity, the heat spreading plate comprising an evaporation end surface and a condensation end surface, the evaporation end surface facing the first opening, the condensation end surface being connected to the cooling plate, the heat spreading plate comprising a plurality of protrusions provided on the condensation end surface, the plurality of protrusions being spaced apart along a first direction of the heat dissipation plate, an end of the cooling plate connected to the heat spreading plate being provided with a plurality of grooves, the plurality of protrusions being provided in the plurality of grooves in a one-to-one correspondence, and a phase change medium being provided inside the heat spreading plate.

2. The heat dissipation plate according to claim 1, wherein the heat spreading plate comprises a capillary wick and is provided with a first vacuum cavity, the phase change medium is provided in the first vacuum cavity, each protrusion is provided with a second vacuum cavity in communication with the first vacuum cavity, and the capillary wick covers at least one of an inner wall of the first vacuum cavity and an inner wall of the second vacuum cavity.

3. The heat dissipation plate according to claim 2, wherein the heat spreading plate comprises a supporting member, one end of the supporting member is connected to the evaporation end surface, and another end of the supporting member is connected to the condensation end surface.

4. The heat dissipation plate according to claim 3, wherein a plurality of supporting members are provided, one end of each supporting member is obliquely arranged with respect to the evaporation end surface, another end of each supporting member is obliquely arranged with respect to the condensation end surface, and the plurality of supporting members are sequentially connected end to end in the first vacuum cavity to form a zigzag line structure.

5. The heat dissipation plate according to claim 3, wherein a plurality of supporting members are provided, one end of each supporting member is vertically connected to the evaporation end surface, and another end of each supporting member is vertically connected to the condensation end surface.

6. The heat dissipation plate according to claim 1, further comprising a limiting portion connected to an end of the frame adjacent to the first opening.

7. The heat dissipation plate according to claim 1, wherein a side of the frame opposite to the first opening is provided with a second opening, an end surface of the cooling plate away from the heat spreading plate faces the second opening, and the liquid inlet and the liquid outlet are both provided on an end surface of the cooling plate away from the heat spreading plate.

8. The heat dissipation plate according to claim 1, further comprising a fastener provided on the frame, wherein the fastener is configured to connect the frame to an element to be cooled.

9. The heat dissipation plate according to claim 8, wherein the fastener comprises two bolts provided on two sides of the frame, respectively, the frame is provided with two connection holes, and the two bolts are connected to the element to be cooled through the two connection holes.

10. A heat dissipation device, comprising a water pump, a first pipeline, a second pipeline, a water tank, and the heat dissipation plate according to claim 1, wherein an output end of the water tank and the liquid inlet of the heat dissipation plate are connected through the first pipeline, the liquid outlet of the heat dissipation plate and an input end of the water tank are connected through the second pipeline, the water tank, the heat dissipation plate, the first pipeline and the second pipeline are sequentially connected to form a circulation system, and the water pump is provided in the circulation system.

11. A computing device, comprising a computing element and the heat dissipation device according to claim 10, the heat dissipation device being mounted on the computing element.
